(19) United States
(12) Patent Application Publication
(10) Pub. No.: US 2020/0381249 A1
(43) Pub. Date: Dec. 3, 2020

(54) METHOD FOR FABRICATING A SEMICONDUCTOR SUBSTRATE

(71) Applicant: SAINT-GOBAIN LUMILOG, Courbevoie (FR)

(72) Inventors: Bernard BEAUMONT, Le Tignet (FR); Jean-Pierre FAURIE, Valbonne (FR)

(73) Assignee: SAINT-GOBAIN LUMILOG, Courbevoie (FR)

(21) Appl. No.: 16/082,073

(22) PCT Filed: Mar. 2, 2017
(86) PCT No.: PCT/EP2017/054918

§ 371 Date: Aug. 5, 2020

(30) Foreign Application Priority Data
Mar. 4, 2016 (FR) 1651853

(51) Int. Cl. H01L 21/02; C30B 29/40; C30B 25/18

(52) U.S. Cl. CPC H01L 21/02458; H01L 21/02513; C30B 29/406; C30B 25/183; H01L 21/02598; H01L 21/02639; H01L 21/02658; H01L 21/02664; H01L 21/02595; H01L 21/0254

(57) ABSTRACT

The invention relates to a method for fabricating a group 13 nitride semiconductor substrate (5) comprising the following steps of: a) deposition of at least one monocrystalline layer (5b) by epitaxial growth (10) on a starting substrate, said monocrystalline laser having an upper face having structural defects that do not pass all the way through (6); b) deposition, by epitaxial growth (30, 35), of at least one continuous polycrystalline layer (5c); c) separation (40) of the starting substrate (1); d) rectification (50) by removing at least one layer thickness corresponding to the thickness of the one or more deposited polycrystalline lasers (5c), the one or more polycrystalline layers (5c) thus being removed with the exception of the zones of the subjacent monocrystalline layer (5b) corresponding to the structural defects that do not pass all the way through (6) that said one or more polycrystalline layers (5c) fill.

### FIELD OF THE INVENTION

The invention relates to the general technical field of the fabrication of substrates and wafers from a semiconductor material based on elements in columns 13 and 15 of the periodic table—such as gallium nitride GaN.

These wafers may be intended for producing semiconductor structures, such as light-emitting diodes (LEDs), or laser diodes (LDs).

### PRIOR ART

Current methods of fabricating semiconductor substrate material based on a column-13 element nitride are based on vapor phase deposition techniques, in particular heteroepitaxy which consists in growing a crystal—such as a crystal of gallium nitride GaN—on a starting substrate of a different nature—such as a sapphire substrate.

These methods involve an injection system from at least two different gaseous components, likely to interact before deposition.

These include well-known methods such as:
MetalOrganic Vapor Phase Epitaxy (MOVPE),
Hydride Vapor Phase Epitaxy (HVPE),
Close-Spaced Vapor Transport (CSVT),
ceramic vapor phase deposition, etc.

The heteroepitaxy method leads to macro-defects known as “pits” in English. This type of defect is a hollow or a permanent pit, or even a hole through the thickness of the deposit, of decreasing cross-section in the opposite direction to the direction of growth and the width and depth of which increase when the thickness of the deposit increases.

Typically such a hole may measure up to 1 mm in diameter and 1.5 mm in depth, unlike dislocation type defects which are of the order of a micrometer in dimension.

Such a hollow (permanent pit) cannot be removed by normal methods of growth, including, for example, alternating 3D/2D growth modes.

These hollows are not desirable, since they have no radiative function and heavily penalize the performance of the diode.

They are all the more damaging as it is generally desired to produce thick deposits, which have a greater crystalline quality. Indeed, the density of crystalline defects, such as dislocations, decreases when the thickness of the deposit increases.

Such non-through or permanent structural holes are, for example, described in document WO2013/144709A2. To remove these non-through holes, the publication WO2013/144709A2 first provides for machining the opposite face to the growth face. Secondly, the through holes thus created are filled by epitaxial growth.

Such a method assumes, however, a machining step separate from the actual deposition process. This method therefore requires an additional step representing added complexity, as well as a substantial additional cost, notably in terms of loss of material.

The publication US2010/0124814 discloses a substrate comprising a monocrystalline layer of a Group III element nitride having growth pits, originating from growth dislocations.

The solution provided by US2010/0124814 is to enclose these pits during the epitaxial growth of the upper layer. An intermediate layer of silicon nitride or oxide is deposited discontinuously on only some portions of the pits and the rest of the monocrystalline layer. This intermediate layer constitutes a discontinuous masking layer that helps reduce nucleation and allows the enclosure of the pits by lateral growth of the upper layer above the hollows.

Such a process greatly reduces the dislocations in the completed structure, thanks to closing up the pits. However, it creates many cavities inside the structure and therefore a high density of hollow non-through structural defects (much higher than 5%).

There is therefore a need for a less complex and more economical method, allowing the fabrication of slices of very homogeneous semiconductor material, having a very low density of non-through macrostructural defects, notably slices of material made of a nitride of an element of group 13 in the periodic table, in particular slices composed of GaN.

### DESCRIPTION OF THE INVENTION

In the context of the present invention, polycrystalline deposit is understood to mean a deposit including crystallized grains of small size or an ordered structure of random orientation, with an orientation not imposed by the medium and disoriented between them thus forming a mosaic.

“Microcrystalline” layer is understood to mean a layer formed of microcrystals or microcrystallites, typically of the order of 0.01 to 10 micrometers in equivalent diameter.

Amorphous layer is understood to mean a layer comprising at least 50% by weight of a disordered orientation or vitreous phase, i.e. not crystallized or microcrystalline.

In view of the problems mentioned above, one aim of the present invention is therefore to reduce, or even eliminate the impact of the macrostructural defects in thick epitaxial layers, typically more than 200 micrometers or even more than 300, or even 500 micrometers or more, during the epitaxy process, i.e. without a separate step from the growth process.

Another objective of the invention is to obtain thick (typically more than 200 micrometers or even more than 300 or even 500 micrometers or more) slices of semiconductor material, offering the best crystalline qualities (double X-ray diffraction (DXD) line width of the order of 100 arcsec or less) and having a surface density of non-through macrostructural defects of less than 5%, preferably less than 2%, or even less than 1.5%.

In this regard, the object of the invention is a method for fabricating a group 13 element nitride semiconductor substrate including the steps of:
deposition of at least one monocrystalline layer by epitaxial growth on a starting substrate, said monocrystalline layer having an upper face having non-through structural defects;
deposition by epitaxial growth of at least one continuous polycrystalline layer;
separation of the starting substrate;
grinding by eliminating at least one thickness of layer corresponding to the thickness of the deposited polycrystalline layer (or layers), the polycrystalline layer (or layers) thus being eliminated, with the exception of the areas of the subjacent monocrystalline layer corresponding to the non-through structural defects filled by said polycrystalline layer (or layers).

Advantageously, but optionally, the method according to the invention may further include at least one of the following features:
during the step of deposition by epitaxial growth of at least one continuous polycrystalline layer, an epitaxial growth is implemented at a temperature of more than 100° C. (preferably more than 200° C. and even more preferably more than 300° C.) below the growth temperature at the time of the deposition of the monocrystalline layer.
during the step of deposition by epitaxial growth of at least one continuous polycrystalline layer an epitaxial growth is implemented at a growth temperature of 700° C. or less, or even 600° C. or less.
during the step of deposition by epitaxial growth of at least one continuous polycrystalline layer an epitaxial growth is implemented at a growth rate greater than 1000 micrometers per hour and/or at least 10 times the growth rate of the monocrystalline layer.
during the step of deposition by epitaxial growth of at least one continuous polycrystalline layer, a preliminary step is implemented of determining non-through structural defects of an equivalent diameter and/or depth of 20 to 1000 micrometers.
during the step of deposition by epitaxial growth of at least one continuous polycrystalline layer a step of depositing a continuous amorphous and/or microcrystalline layer is previously implemented over the entire upper face of the monocrystalline layer.
   the amorphous and/or microcrystalline layer is a silicon- or silicon nitride-based layer.
   the amorphous and/or microcrystalline layer has a thickness of 0.1 to 0.5 micrometer, preferably less than 0.2 micrometer.
   the deposition of the amorphous and/or microcrystalline layer has a growth temperature of between 900° C. and 1150° C.
the monocrystalline layer is a group 13 element nitride layer.
the group 13 element nitride monocrystalline layer is a layer of gallium nitride.
the polycrystalline layer is a group 13 element nitride layer.
the group 13 element nitride polycrystalline layer is a layer of gallium nitride.
the microcrystalline layer has a thickness greater than 300 micrometers, or greater than 500 micrometers.
the polycrystalline layer has a thickness of between 0.1 and 1 mm, or between 0.1 and 0.5 mm.

The object of the invention is also a substrate of element group 13 semiconductor material including on its upper face at least one monocrystalline layer having non-through structural defects of an equivalent diameter and/or depth of 20 to 1000 micrometers filled with at least one continuous polycrystalline layer, said substrate having a thickness of at least 300 micrometers, and a double X-ray diffraction line width of the order of 100 arcsec or less, preferably of 80 arcsec or less, or of the order of 60 arcsec or less. The object of the invention is also a group 13 element nitride wafer having a double X-ray diffraction line width of the order of 100 arcsec or less, preferably of 80 arcsec or less, or of the order of 60 arcsec or less.

### DESCRIPTION OF THE FIGURES

Other features, aims and advantages of the present invention will appear on reading the following detailed description, referring to the appended figures, given by way non-restrictive examples, in which:

FIG. 1 summarizes the main steps of the method for fabricating a substrate according to an implementation of the invention.

FIG. 2 schematically represents a semiconductor material composed of a stack of layers according to the invention.

FIG. 3A illustrates the steps of deposition (plugging) with a polycrystalline layer, then of grinding according to a first possible implementation of the invention,

FIG. 3B illustrates the steps of deposition (plugging) with a polycrystalline layer, then of grinding according to a second possible implementation of the invention,

FIG. 4 comparatively illustrates the implementation of the same steps with a step of deposition (plugging) with a layer of a monocrystalline layer,

FIG. 5A illustrates a self-supported group 13 element nitride crystal obtained according to a possible implementation of the invention.

FIG. 5B illustrates a self-supported group 13 element nitride crystal obtained, after grinding according to a possible implementation of the invention.

### DETAILED DESCRIPTION OF AT LEAST ONE EMBODIMENT OF THE INVENTION

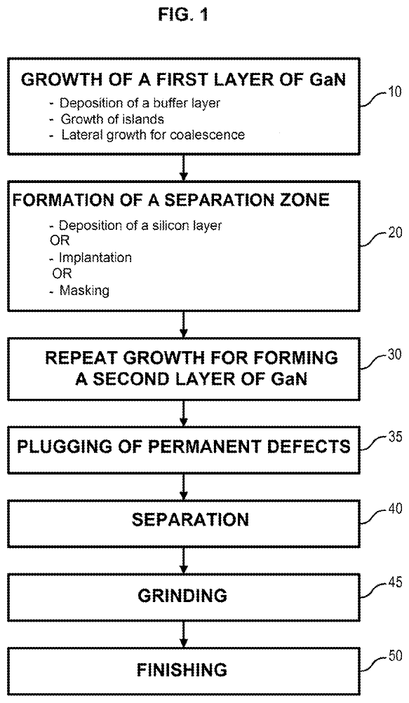

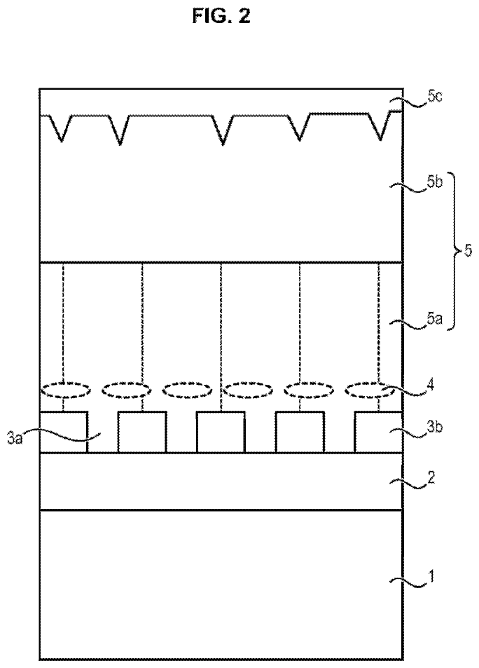

The major phases of the method for fabricating GaN wafers are illustrated with reference to FIGS. 1 and 2.

In the following, a description will be given of the method according to the invention with reference to the fabrication of gallium nitride GaN wafers.

However, it is obvious to the person skilled in the art that the method described below may be used for growing a material including a group 13 element nitride layer other than gallium nitride GaN.

1. Method of Fabrication

The method includes:
a growth phase 10 of a first layer of group 13 element nitride preferably GaN 5a;
a formation phase 20 of a zone of separation 4;
a repeat epitaxy phase 30 for forming a second thick layer of GaN 5b;
a plugging phase 35 of the hollow or pit type non-through structural defects;
a separation phase 40 for obtaining a GaN crystal 5;
a grinding phase 45 for removing a thickness of the second thick layer of GaN 5b;
a finishing phase 50 for forming GaN wafers from the GaN crystal 5.

1.1. Growth Phase 10

The growth phase 10 consists in forming a first layer of GaN 5a by lateral overgrowth.

The lateral overgrowth helps minimize the density of defects contained in the first layer of GaN 5a.

The approach used for reducing the density of dislocations in the first layer of GaN 5a consists in:
initiating a growth mode of GaN by islands, then in
encouraging the coalescence of the islands in order to obtain the first layer of GaN 5a.

Advantageously, the lateral overgrowth is implemented on a starting substrate 1 having a non-zero truncation angle.

The fact of using a starting substrate 1 having a non-zero truncation angle makes it possible to grow a first layer of GaN 5a having a non-zero truncation angle. The truncation angle may be between 0.1 and 5 degrees, preferably between 0.2 and 0.8 degree, and even more preferably between 0.3 and 0.6 degree (notably for limiting the stacking faults).

The starting substrate 1 may be chosen from among Si, AlN, GaN, GaAs, Al2O3 (sapphire), ZnO, SiC, LiAlO2, LiGaO2, MgA2O4, 4H—SiC, or any other type of starting substrate known to the person skilled in the art for implementing a growth of gallium nitride. It may have a thickness of a few hundred micrometers, generally 350 micrometers.

Advantageously, the starting substrate 1 may be treated by nitriding prior to any step of deposition. This helps improve the quality of the GaN crystal obtained.

The growth of the first layer of GaN 5a may be implemented according to different variants. Notably, the lateral overgrowth may be based:
on the use of a dielectric mask 3a, 3b including openings 3a wherein the islands are formed, as described in document WO99/20816;
on the use of a dielectric layer devoid of any opening whereon islands are formed spontaneously, as described in document EP 1 338 683.

1.1.1. First Variant of Lateral Overgrowth

In a first variant, the growth phase 10 consists of an Epitaxial Lateral Overgrowth (hereinafter referred to as “ELO”).

The ELO includes a step of deposition of a buffer layer 2 on the starting substrate 1.

This deposition is preferably performed by MetalOrganic Vapor Phase Epitaxy (or “MOVPE”), e.g. at a temperature of between 500° C. and 700° C., notably of 600° C.

The deposition of a buffer layer 2 helps reduce the stresses between the starting substrate 1 and the first layer of GaN 5a subsequently epitaxied thereon. Indeed, the deposition of the buffer layer 2 on the substrate 1 helps ensure a “soft” transition between the substrate 1 and the first layer of GaN 5a the crystalline structures of which are different.

The deposition of the buffer layer 2 further helps facilitate the subsequent separation of the GaN crystal 5, as will emerge from the following description. The buffer layer 2 is, for example, a layer of GaN, a layer of AlN, or a layer of AlGaN.

In another step, a mask 3a, 3b including openings 3a is formed. The openings 3a may be isolated or in the form of strips, and make it possible to define positions for the subsequent selective growth of islands of GaN.

The mask 3a, 3b may be a mask made of dielectric material, e.g. SiNx (SiN, Si3N4, etc.) or SiO2 or TiN. This helps minimize the defects created at the mask edge and thus improves the quality of the layer of GaN subsequently epitaxied thereon.

The formation of the mask 3a, 3b may be achieved by any technique known to the person skilled in the art. For example, the formation of the mask may consist in:
the deposition of a dielectric layer 3a from gaseous precursors of silane and ammonia directly onto the buffer layer 2, and
the etching by photolithography of the dielectric layer 3a for forming openings 3a.

Thus a starting substrate 1 is obtained covered with a buffer layer 2 and a mask 3a, 3b. In addition to its function of improving the quality of the first layer of GaN 5a (by filtering the through defects), the mask 3a, 3b helps weaken the interface between the starting substrate 1 and the first layer of GaN 5a.

Another step consists in forming islands of GaN through the openings 3a of the mask. The growth rate along an axis orthogonal to the main plane of the starting substrate 1 is maintained higher than the lateral growth rate. Thus islands or strips with triangular cross-sections are obtained (depending on the shape of the openings 3a). Inside these strips with a triangular cross-section, the through dislocations are bent to 90°.

This is followed by a lateral overgrowth to finally end up with a flat ELO layer. At the end of this step of the method a first layer of GaN 5a is obtained having a dislocation density of less than 10⁷ cm⁻².

1.1.2. Second Variant of Lateral Overgrowth

In a second variant, the growth phase 10 consists of a Universal Lateral Overgrowth (hereinafter referred to as a “ULO”) as described in document EP 1 977 028.

The ULO includes a step of deposition of a nucleation layer on the starting substrate 1. The nucleation layer is, for example, a very thin film of silicon nitride SiN, of the order of a few atomic planes, in other words of the order of 10 nm to 20 nm in thickness. The deposition of SiN based on silane and ammonia may last 360 seconds.

A continuous buffer layer 2—e.g. of GaN—is then deposited on the nucleation layer. The deposition of the buffer layer 2 of GaN makes it possible to filter the crystalline defects and thus minimize from the start of the method the density of defects that will be present in the first layer of GaN 5a subsequently epitaxied.

The thickness of this buffer layer 2 of GaN may be between 10 and 100 nm. The temperature during this operation may be between 500° C. and 700° C.

This is followed by a high temperature annealing at between 900° C. and 1150° C. Under the joint effect of the temperature rise, the presence in the gaseous vehicle of a sufficient quantity of hydrogen and the presence of the very thin film of SiN, the morphology of the buffer layer 2 of GaN undergoes a profound change resulting from a solid phase recrystallization by mass transport. The initially continuous buffer layer 2 of GaN is then converted into a discontinuous layer of GaN patterns. Thus patterns or islands of GaN of very good crystalline quality are obtained, these retaining an epitaxial relationship with the starting substrate thanks to the very small thickness of the nucleation layer.

The areas where the silicon nitride SiN is stripped bare then function as a mask and the GaN patterns function as areas of GaN located in the openings made ex situ in the mask. This is followed by a lateral overgrowth to finally to end up with a flat ULO layer.

This method, wherein the silicon nitride mask forms spontaneously, and which involves the same mechanisms of bending the dislocations as in the ELO, is identified as “ULO” (or “spontaneous ELO”).

1.2. Formation Phase 20 of a Separation Zone 4

The method further includes a formation phase 20 of a separation zone 4.

This formation phase 20 of a separation zone may be implemented according to different variants. In particular, the formation phase 20 of the separation zone may be implemented:
prior to the growth phase 10 of the first layer of GaN (first variant), or
subsequently to the growth phase 10 of the first layer of GaN (second variant), or
during the growth phase 10 of the first layer of GaN (third variant).

1.2.1. First Variant of Formation of the Separation Zone 4

In a first variant, the formation phase 20 of a separation zone 4 may consist in depositing an intermediate layer of silicon Si, prior to the growth phase 10 of the first layer of GaN 5a, as described in EP 1 699 951.

The intermediate layer of silicon Si serves as a sacrificial layer intended to be spontaneously vaporized during the subsequent phase of growth by epitaxy of the first layer of GaN 5a.

The spontaneous vaporization of the intermediate layer of silicon Si during the growth phase of the first layer of GaN 5a helps reduce the density of crystalline defects (in particular of dislocations) inside the first layer of GaN 5a.

1.2.2. Second Variant of Formation of the Separation Zone

In a second variant, the formation phase 20 of a separation zone 4 includes a step of implantation performed after the growth phase 10 of the first layer of GaN 5a. This implantation allows the creation of a weakened zone in the first layer of GaN 5a.

Implantation consists in bombarding the first layer of GaN 5a with ions so as to create a layer of microcavities (or bubbles) in the semiconductor, at a depth close to the average depth of penetration of these ions.

The implanted ions may be selected from among tungsten, helium, neon, krypton, chromium, molybdenum, iron, hydrogen, or boron. Preferably, the implanted ions are tungsten ions. These display the particular feature of decomposing the GaN.

In terms of dose, when the implanted ions are H+ ions, the dose of implanted ions may be between 10¹⁶ and 10¹⁷ cm⁻², and the depth of implementation may vary between 0 nm and 50 nm from the free surface—referred to as the growth face—of the first layer of GaN 5a.

The implantation of weakening ions may be implemented in a single step or in successive steps. The temperature may be between 4 K and 1000 K in the implantation step.

1.2.3. Third Variant of Formation of the Separation Zone

In a third variant, the separation zone 4 may be formed during the growth phase 10 of the first layer of GaN 5a.

Notably when the growth phase is carried out according to the first “ELO” variant embodiment (i.e. deposition of a dielectric mask 3a, 3b), the formation phase 20 of the separation zone 4 may include the implantation of the buffer layer 2 prior to the deposition of the mask 3a, 3b.

This makes it possible to place the separation zone 4 at a precisely desired depth due to the fact that the first layer of GaN 5a deposited in the ELO overgrowth step does not hinder ion implantation.

Of course, the implantation may be carried out at various stages of the ELO (or ULO) lateral growth phase, either in the islands, or at an intermediate stage where the islands are not entirely coalesced, or after total coalescence of the islands.

1.3. Repeat Epitaxy Phase 30

At the end of the formation phase 20 of a separation zone 4 and growth phase 10 of the first layer of GaN 5a, the method includes a repeat epitaxy phase 30 for forming a second thick layer of GaN 5b. This repeat epitaxy may be implemented by:
MetalOrganic Vapor Phase Epitaxy (“MOVPE”),
Hydride Vapor Phase Epitaxy (“HVPE”),
Close-Spaced Vapor Transport (“CSVT”), or else by
Liquid Phase Epitaxy (“LPE”).

It is preferred in this step to implement the “HVPE” technology which allows obtaining three main interesting effects:
a first effect is that the first layer of GaN 5a is thickened without losing its crystalline qualities (neither a new dislocation nor a crack is generated).
a second effect is that the dislocation density is further reduced during HVPE repeat epitaxy, by a factor at least equal to 2.
a third effect is that the thick layer of GaN 5 thus obtained spontaneously separates from its starting substrate 1 at the level of the separation zone 4.

Thus a second layer of monocrystalline GaN 5b is obtained extending over the first layer of GaN 5a. The second layer of monocrystalline GaN 5b has a non-zero truncation angle of constant value on its front face.

The conditions of growth of this second monocrystalline layer 5b are typically a growth temperature of between 900° C. and 1150° C., with a growth rate that may be between 50 and 500 micrometers per hour, preferably between 100 and 150 micrometers per hour.

The monocrystalline layer has a thickness greater than 300 micrometers, or preferably greater than 500 micrometers and exhibits hollow or pit type non-through structural macrodefects.

1.4. Phase of Plugging Non-Through Structural Defects

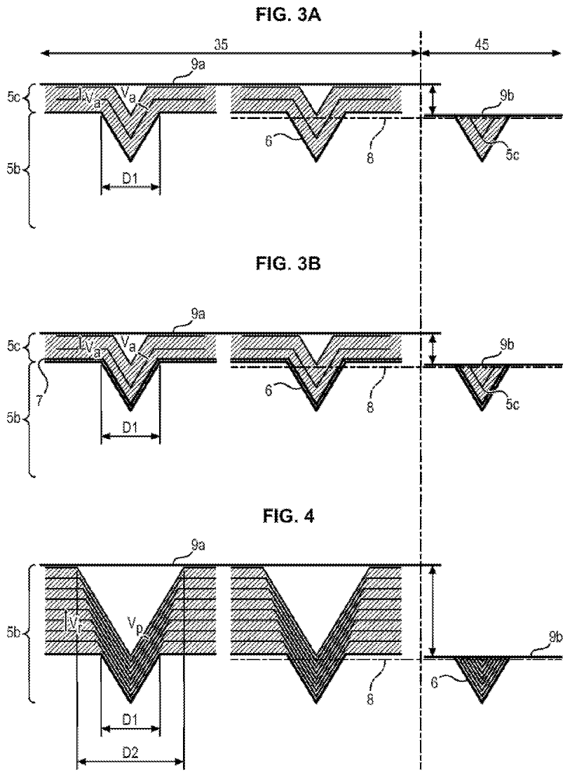

FIGS. 3A and 3B illustrate the step of plugging 35 non-through structural macrodefects 6 according to various possible implementations of the invention described below.

In a preliminary step, the non-through permanent or structural macrodefects 6 are determined on typical samples.

Typically, non-through permanent or structural macrodefects 6 will have an equivalent diameter of between 20 and 1000 micrometers.

The equivalent diameter of a permanent defect is its largest dimension of opening determined by observation under an optical microscope.

This step of measuring the size of defects and seeking the largest diameter and greatest depth for a layer 5b of given thickness makes it possible to calibrate the method with a view to determining the time to allocate to the step of plugging 35 in order to obtain a layer 5c filling the non-through permanent or structural macrodefects 6 of the monocrystalline layer 5b.

The thickness of the layer 5c is between 50% and 100% of the value of the largest equivalent diameter of the non-through structural macrodefects 6.

A defect equivalent diameter is determined, corresponding to the diameter of a perfect disk of the same area as that measured for said defect.

The largest equivalent diameter is identified statistically on a batch of crystal 5 samples. By observing the surface of the layer 5b of the crystal 5 under a microscope, the macrodefects are examined along a horizontal axis of the crystal 5 taken at random, and along a second horizontal axis perpendicular to this first axis, and the equivalent diameter of these macrodefects is measured. The depth is measured by moving the micrometer screw of the microscope optic allowing adjustment in order to observe the surface of the defect and the bottom of the defect. The defect with the largest surface and the greatest depth is the defect taken into account in order to adjust the parameters of the phase of plugging.

The surface density of macrodefects may be determined by dividing the sum of the areas of each permanent defect, the surface of which is the aforementioned disk of equivalent diameter, over the surface of the crystal layer after plugging, or over that of the wafer after finishing, observed via optical microscopy.

This is followed by the phase of plugging the non-through structural defects by continuing the deposition under the conditions, described below, appropriate for creating the deposition of a continuous polycrystalline layer 5c of group 13 element nitride covering the entire upper face of the subjacent layer 5b, and which may comprise a thickness of between 0.1 and 1 mm, preferably 0.1 to 0.5 mm.

According to a first possible implementation of the invention of the step of plugging 35, as illustrated in FIG. 3A, the growth temperature is greatly reduced by 100° C., preferably by more than 200° C. or even by more than 300° C. and/or the growth rate is strongly increased.

Thus, the growth temperature is lowered to 700° C. or less, or even 600° C. or less, and the increased growth rate is at least 10 times greater than that of the growth of the layer 5a or 5b, in particular greater than 1000 micrometers per hour. These deposition conditions indeed allow the growth of the polycrystalline layer Sc directly on the monocrystalline layer 5b.

Under these extreme conditions, the deposition deteriorates to the point of creating a polycrystalline deposit.

This first possible implementation of the invention allows very good adhesion of the polycrystalline layer 5c on the subjacent monocrystalline layer 5b. The polycrystalline layer 5c filling in or filling up the hollows or pits 6 is sufficiently consolidated for undergoing machining in a step of grinding 45, described below in the description.

According to a second possible implementation of the invention of the step of plugging 35, as illustrated in FIG. 3B, a step of deposition of a continuous amorphous and/or microcrystalline layer 7 is performed. This step may be performed before the step of plugging 35.

This deposition of a continuous amorphous and/or microcrystalline layer 7 is performed in order to block the epitaxy of the next layer and also to more easily form said polycrystalline layer of the phase of plugging 35.

Preferably the layer 7 is rather amorphous, oxide and/or nitride, preferably silicon-based, preferably silicon nitride-based. A preliminary deposition of amorphous SiN is particularly suitable as it adheres perfectly to the monocrystalline layer of group 13 element nitride, particularly in the case of GaN.

Such an amorphous deposition 7 typically has a thickness of 0.1 to 0.5 micrometer, preferably less than 0.2 micrometer. The deposition rate of such a layer is, for example, from 0.1 to 0.2 micrometer per hour.

Next, the growth process is repeated and the non-through structural defects 6 are filled in with a polycrystalline layer of GaN 5c.

Once this repeated growth has been induced, growth conditions of temperature and pressure quite similar to those for the deposition of the monocrystalline layer 5b are adopted.

The deposition of this polycrystalline layer 5b may therefore be carried out in the temperature range used for the growth of the monocrystalline layer 5a, i.e. between 900° C. and 1150° C.

Thus, this possible implementation of the invention advantageously saves time, the conditions of the reactor not varying between the formation of the different layers 5b and 5c.

Furthermore, the particular advantage of this second implementation is to fill the hollows 6 without creating new structural defects within the first monocrystalline layer 5a and without creating any mechanical stresses on the second layer 5b.

Advantageously, in this second implementation of the invention, for optimizing the duration and if necessary accentuating the polycrystalline nature of this layer, the growth rate may be increased and/or the growth temperature reduced for the polycrystalline GaN layer, in similar conditions to the first possible implementation of the invention described above.

The deposition of a polycrystalline layer of GaN on the upper surface of a monocrystalline layer of GaN is known to the prior art, however, the deposition of a polycrystalline layer in order to plug non-through structural defects 6 is unknown to the prior art.

Thus, document U.S. Pat. No. 8,349,711B2 provides a polycrystalline deposition in order to mechanically reinforce a monocrystalline layer. It is thus explained that such a layer may be obtained by reducing the growth temperature by 20° C. to 990° C. and by increasing the ammonia flow from 1600 to 6000 sccm (“standard cubic centimeters per minute” or 1 cm³ per minute at 0° C. and under a pressure of 1 bar). The HCl flow is kept at 120 sccm for a growth rate of 330 μm/hour.

This rate is, however, extremely low and is insufficient for filling in the non-through macrodefects, observed on thick layers, such as those in the present invention.

Document US2012/0015143 discloses a monocrystalline substrate with a textured surface for the epitaxial growth of single crystals. The surface texture is obtained by depositing a polycrystalline deposit on the single crystal. The polycrystalline layer is deposited then chemically treated in order to attack the grain boundaries and obtain a nano-structured surface. The polycrystalline layer is therefore only used for the purpose of structuring the substrate, it is not used for the purpose of filling in the non-through structural defects of a monocrystalline layer.

Thus, advantageously and unknown to the prior art, the invention provides a method of plugging 35 non-through structural defects 6 of a monocrystalline layer 5b by the deposition of a polycrystalline layer 5c.

It will be noted with reference to FIG. 4 that if a person skilled in the art were to envisage filling in the non-through defects 6 by continuous depositions, they would naturally carry out plugging by monocrystalline growth.

Nevertheless, such an implementation would not be satisfactory.

In particular, the growth rate is not uniform between the areas with and without non-through defects. Thus the growth rate Vr on a plane without structural defects will be greater than the growth rate Vp on a plane having a hollow. Accordingly, the diameter of the hollows 6, widens as the monocrystalline layer grows, the equivalent diameter D2 of the hollows after plugging is greater than the equivalent diameter D1 before plugging, the structural defect therefore expands.

In comparison, in the case of a polycrystalline growth, such as proposed and illustrated in FIGS. 3A and 3B, the growth rate Va is constant over all the growth planes; the diameter of the hollows 6 therefore also remains constant during the growth of the polycrystalline layer.

Furthermore, the deposition of polycrystalline layers requires a smaller thickness of material for filling in non-through defects 6 in the first monocrystalline layer 5b. The method provided is therefore less expensive.

1.5. Separation Phase 40

A separation phase 40 is also implemented, it is dependent on the variant implemented for the formation phase 20 of the separation zone 4.

In the case of ion implantation, the spontaneous separation phase 40 takes place due to the thermal cycle (repeat epitaxy at high temperature and cooling) undergone by the thickened layer of GaN 5 which, because of the difference in thermal expansion coefficients between the starting substrate 1 and the thick layer of GaN 5, generates stresses causing its separation.

In the case of the deposition of an intermediate silicon layer, this separation occurs during the repeat epitaxy by spontaneous vaporization of the intermediate silicon layer.

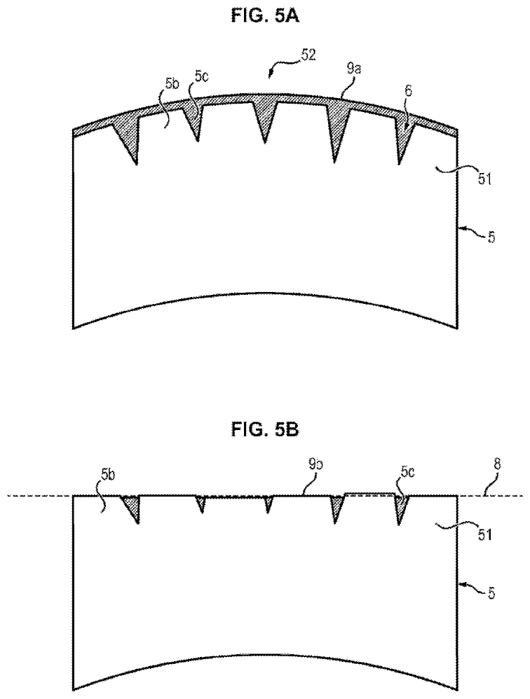

Thus a self-supported GaN crystal 5 is obtained as illustrated in FIG. 5.

As is common in HVPE, the GaN crystal 5, as illustrated in FIG. 5A, includes excrescences 51 in the form of hexagonal pyramids on a front face 52, delimiting non-through macrostructural pits or defects 6 in the monocrystalline area 5b and polycrystalline areas 5c.

Such a crystal is domed and has a radius of curvature of less than 25 meters and preferably less than 20 meters (radius of curvature of the front face 52, like the face of the crystal opposite said front face 52).

In the example of FIG. 5A, this radius of curvature is 5 meters or more; moreover, the crystal 5 furthermore has a dislocation density of 10⁷ cm⁻² or less.

The GaN crystal 5 having been formed on a starting substrate with a non-zero truncation angle, it also has a non-zero truncation angle, the orientation of the crystal planes being propagated from one layer to another. For example, in the case of a sapphire substrate 1 with a truncation angle equal to 4 degrees, the growth face of the crystal 5 has a truncation angle equal to 4 degrees over its entire surface.

1.6. Grinding Phase 45

Once the GaN crystal 5 is separated from the starting substrate 1, the final layer of group 13 element nitride is eliminated in order to remove the polycrystalline layer 5c over its entire thickness except at said structural defects 6. Such a crystal, after grinding, is represented in FIG. 5B.

Preferably, the elimination 45 of the polycrystalline layer is carried out by machining, e.g. by grinding.

Current techniques make it possible to control the elimination of a layer thickness to within 10 micrometers. The elimination in particular of a polycrystalline layer 5c composed of gallium nitride (GaN and variants GaAlN, GaInN, etc.) is only actually possible by mechanical machining, chemical attack being insufficient in this specific case.

The upper face 9a of the GaN crystal 5 is eliminated by machining to a grinding level 8, after grinding defining an upper face 9b, as illustrated in FIGS. 3A and 3B. This grinding level 8 corresponds to the thickness of the deposited polycrystalline layer (or layers) 5c, the polycrystalline layer (or layers) 5c thus being eliminated, with the exception of the areas of the monocrystalline layer 5b corresponding to the non-through structural defects 6 filled with said polycrystalline layer (or layers) 5c.

After the separation 40 and grinding 45 phases, the result obtained is a substrate of group 13 element nitride semiconductor material (5) including on its upper face (9b) at least one monocrystalline layer (5b) having discontinuities (6) corresponding to non-through structural defects of an equivalent diameter and/or depth of 20 to 1000 micrometers plugged or filled with at least one continuous polycrystalline layer (5c), said substrate having a thickness of at least 300 micrometers. In addition, advantageously, said substrate has a double X-ray diffraction line width of the order of 100 arcsec or less, preferably of 80 arcsec or less, or of the order of 60 arcsec or less.

The comparison between FIGS. 3A, 3B and FIG. 4 clearly shows the advantage of the method according to the invention. As explained, in step 35, the plugging being carried out with a more uniform growth rate in the method according to the invention, the plugging is carried out faster, the loss of material to machining is therefore less than with a substrate plugged by monocrystalline deposition, the thickness of layer removed being markedly less in the case of a polycrystalline deposition.

Furthermore, in the method of FIG. 3, the machining material loss is essentially of the amorphous or polycrystalline type, it is a less noble material and therefore less expensive than monocrystalline material.

1.7. Finishing Phase 50

Next comes the finishing operation for forming GaN wafers having a double X-ray diffraction line width of the order of 100 arcsec or less, preferably of 80 arcsec or less, or of the order of 60 arcsec or less.

The rear face and the sides or edges of the wafer are ground, polishing them in order to obtain a surface state acceptable for producing semiconductor structures, such as light-emitting diodes (LEDs), or laser diodes (LD).

Thus, the method provided is particularly suitable for fabricating slices of semiconductor material, notably slices of material of an element of group 13 and 15 of the periodic table, more particularly slices composed of a group 13 element nitride, preferably GaN, of large size, greater than 5 centimeters, more than 10 centimeters or even 15 to 20 centimeters.

The slice of semiconductor material according to FIGS. 3A and 3B, formed according to the method of the invention, has a thickness of the order of 450 micrometers and an excellent crystalline quality with a double X-ray diffraction line width of the order of 60 to 80 arcsec, and a surface density of non-through structural defects 6 of the order of 1.3%. While the slice in FIG. 4, formed by plugging with a monocrystalline layer, has a crystalline quality of 130 to 150 arcsec, for a similar surface density of non-through structural defects 6.

In the preceding description the method according to the invention has been described with reference to the fabrication of a substrate of semiconductor material composed of a group 13 element nitride, preferably of GaN. However, it is obvious to the person skilled in the art that the method described above may be used for the fabrication of a substrate including a group 13 element nitride other than gallium nitride GaN, this material being capable of being used for producing semiconductor structures such as light-emitting diodes.

1. A method for fabricating a semiconductor substrate (5) of a group 13 element nitride including the following steps of:
a) deposition of at least one monocrystalline layer (5b) by epitaxial growth (10) on a starting substrate, said monocrystalline layer having an upper face having non-through structural defects (6);
b) deposition (30, 35) of at least one continuous polycrystalline layer (5c);
c) separation (40) of the starting substrate (1);
d) grinding (50) by eliminating at least one thickness of layer corresponding to the thickness of the deposited polycrystalline layer (or layers) (5c), the polycrystalline layer (or layers) (5c) thus being eliminated, with the exception of the areas of the subjacent monocrystalline layer (5b) corresponding to the non-through structural defects (6) filled by said polycrystalline layer (or layers) (5c).

2. The fabrication method as claimed in claim 1, wherein step b) implements a growth at a temperature of more than 100° C. (preferably more than 200° C. and even more preferably more than 300° C.) below the growth temperature at the time of the deposition of the monocrystalline layer.

3. The fabrication method as claimed in claim 1, wherein step b) implements a growth at a growth temperature of 700° C. or less, or even 600° C. or less.

4. The fabrication method as claimed in claim 1, wherein step b) implements a growth at a growth rate greater than 1000 micrometers per hour and/or at least 10 times the growth rate of the subjacent monocrystalline layer (5b).

5. The fabrication method as claimed in claim 1, wherein step b) comprises a preliminary step of determining non-through structural defects of an equivalent diameter and/or depth of 20 to 1000 micrometers.

6. The fabrication method as claimed in claim 1, wherein step b) is preceded by a step of deposition of a continuous amorphous and/or microcrystalline layer over the entire upper face of the monocrystalline layer.

7. The fabrication method as claimed in claim 6, wherein the amorphous layer is a silicon-based or silicon nitride-based layer.

8. The fabrication method as claimed in claim 6, wherein the amorphous layer has a thickness of 0.1 to 0.5 micrometer, preferably less than 0.2 micrometer.

9. The fabrication method as claimed in claim 6, wherein the deposition of the amorphous and/or microcrystalline layer has a growth temperature of between 900° C. and 1150° C.

10. The fabrication method as claimed in claim 1, wherein the monocrystalline layer is a group 13 element nitride layer.

11. The fabrication method as claimed in the preceding claim, wherein the group 13 element nitride layer is a layer of gallium nitride.

12. The fabrication method as claimed in claim 1, wherein the polycrystalline layer is a group 13 element nitride layer.

13. The fabrication method as claimed in the preceding claim, wherein the group 13 element nitride layer is a layer of gallium nitride.

14. The fabrication method as claimed in claim 1, wherein the monocrystalline layer has a thickness greater than 300 micrometers, or greater than 500 micrometers.

15. The fabrication method as claimed in claim 1, wherein the polycrystalline layer has a thickness of between 0.1 and 1 mm, or between 0.1 and 0.5 mm.

16. A group 13 element nitride wafer capable of being obtained by implementing the method as claimed in claim 1 and having a double X-ray diffraction line width of the order of 100 arcsec or less, preferably of 80 arcsec or less, or preferably of 60 arcsec or less.

17. A substrate of element group 13 nitride semiconductor material (5) including on its upper face (9b) at least one monocrystalline layer (5b) having non-through structural defects of an equivalent diameter and/or depth of 20 to 1000 micrometers filled with at least one continuous polycrystalline layer (5c), said substrate having a thickness of at least 300 micrometers, and a double X-ray diffraction line width of the order of 100 arcsec or less, preferably of 80 arcsec or less, or of the order of 60 arcsec or less.
